(19) United States
(12) Patent Application Publication
(10) Pub. No.: US 2026/0068044 A1
(43) Pub. Date: Mar. 5, 2026

(54) WIRING CIRCUIT BOARD AND METHOD OF PRODUCING THE WIRING CIRCUIT BOARD

(71) Applicant: NITTO DENKO CORPORATION, Osaka (JP)

(72) Inventors: Kenta FUKUSHIMA, Osaka (JP); Shusaku SHIBATA, Osaka (JP); Yusaku TAMAKI, Osaka (JP)

(73) Assignee: NITTO DENKO CORPORATION, Osaka (JP)

(21) Appl. No.: 19/311,817

(22) Filed: Aug. 27, 2025

(30) Foreign Application Priority Data
Aug. 30, 2024 (JP) 2024-150254

(51) Int. Cl. H05K 1/05; H05K 1/09; H05K 3/12

(52) U.S. Cl. CPC H05K 1/056; H05K 1/09; H05K 3/1283; H05K 2201/0269

(57) ABSTRACT

A wiring circuit board has a metal support substrate, a base insulating layer disposed on a one-side surface of the metal support substrate in a thickness direction, and a conductor layer disposed on a one-side surface of the base insulating layer in the thickness direction. The metal support substrate and/or the conductor layer contain(s) a copper alloy, and the copper alloy contains a first metal consisting of copper and a second metal that can be alloyed with copper. In the metal support substrate and/or the conductor layer, the copper alloy has a sea-island structure including a sea portion having a continuous shape and an island portion having a discontinuous shape.

### CROSS-REFERENCE TO RELATED APPLICATION

The present application claims priority from Japanese Patent Application No. 2024-150254 filed on Aug. 30, 2024, the content of which is hereby incorporated by reference into this application.

### TECHNICAL FIELD

The present invention relates to a wiring circuit board and a method of producing the wiring circuit board.

### BACKGROUND ART

Conventionally, in the field of wiring circuit boards, use of an alloy containing copper (hereinafter referred to as a copper alloy) has been considered. More specifically, the following substrate for suspension has been proposed. That is, the substrate for suspension includes a metal support substrate, a base insulating layer formed on the metal support substrate, and a plurality of wires formed on the base insulating layer. The metal support substrate is formed of a copper alloy-based spring material (see, for example, Patent Document 1).

### Citation List

### Patent Document

Patent Document 1: Japanese Unexamined Patent Publication No. 2013-168206

### SUMMARY OF THE INVENTION

### Problem to be Solved by the Invention

Meanwhile, the above-described metal support substrate may be required to have relatively excellent conductivity. For example, the metal support substrate may be used as a jumper wiring, or may be used as a ground layer. In such a case, the metal support substrate is required to have excellent conductivity.

However, the conductivity of the above-described copper alloy-based spring material may not be sufficient. It is also considered to use a copper alloy in place of copper as the above-described wiring. In such a case, relatively excellent mechanical strength is obtained. However, in such a case, the conductivity of the wiring may not be sufficient from the viewpoint of the transmission characteristics of the electrical signal. Therefore, when the wiring circuit board contains a copper alloy, the improvement of the conductivity of the copper alloy is required.

The present invention is a wiring circuit board containing a copper alloy and having both excellent mechanical strength and excellent conductivity, and a method of producing the same.

### Means for Solving the Problem

The present invention [1] includes a wiring circuit board comprising: a metal support substrate; a base insulating layer disposed on a one-side surface of the metal support substrate in a thickness direction; and a conductor layer disposed on a one-side surface of the base insulating layer in the thickness direction, wherein the metal support substrate and/or the conductor layer contain(s) a copper alloy, wherein the copper alloy contains: a first metal consisting of copper; and a second metal that can be alloyed with the copper, and wherein in the metal support substrate and/or the conductor layer, the copper alloy has a sea-island structure including a sea portion having a continuous shape and an island portion having a discontinuous shape.

In the wiring circuit board of the above-described [1], the metal support substrate and/or the conductor layer contain(s) a copper alloy, and the copper alloy contains a first metal consisting of copper and a second metal that can be alloyed with copper. Therefore, the above-described wiring circuit board has excellent mechanical strength.

The above-described copper alloy has a sea-island structure, and the sea-island structure includes a sea portion having a continuous shape and an island portion having a discontinuous shape. Therefore, the above-described wiring circuit board has excellent conductivity derived from the sea-island structure.

As a result, the above-described wiring circuit board has both excellent mechanical strength and excellent conductivity.

The present invention [2] includes the wiring circuit board described in the above-described [1], wherein with respect to an atomic ratio of the second metal in the island portion, an atomic ratio of the second metal in the sea portion is 0.9 times or less.

In the wiring circuit board of the above-described [2], with respect to the atomic ratio of the second metal in the island portion, the atomic ratio of the second metal in the sea portion is a predetermined value or less. That is, the atomic ratio of copper is relatively high in the sea portion having a continuous shape. Therefore, the above-described wiring circuit board has more excellent conductivity.

The present invention [3] includes the wiring circuit board described in the above-described [1] or [2], wherein the second metal is titanium.

In the wiring circuit board of the above-described [3], the second metal is titanium. That is, the copper alloy is a copper-titanium alloy. Therefore, the above-described wiring circuit board has more excellent mechanical strength.

The present invention [4] includes the wiring circuit board described in any one of the above-described [1] or [3], wherein in an XRD chart obtained by measuring an X-ray diffraction (XRD) of the copper alloy, a peak having a peak top in a range of 2θ values of 41.00° or more to 42.00° or less is confirmed.

In the wiring circuit board of the above-described [4], when the X-ray diffraction (XRD) of the copper alloy is measured, a peak having a peak top in a range of 2θ values of 41.00° or more to 42.00° or less is confirmed in the XRD chart. Such a copper alloy has a particularly excellent sea-island structure. Thus, the above-described wiring circuit board has both excellent mechanical strength and excellent conductivity.

The present invention [5] includes the wiring circuit board described in any one of the above-described [1] or [4], wherein a number-average particle diameter of the island portion is 50 nm or more, the number-average particle diameter being measured by using a scanning electron microscope (SEM).

In the wiring circuit board of the above-described [5], the number-average particle diameter of the island portion is a predetermined value or more. That is, in the above-described wiring circuit board, the copper alloy has a particularly excellent sea-island structure. Therefore, the above-described wiring circuit board has both excellent mechanical strength and excellent conductivity.

The present invention [6] includes a method of producing the wiring circuit board described in any one of the above-described [1] or [5], the method including: a step of preparing a metal support substrate; a step of forming a base insulating layer on a one-side surface of the metal support substrate in a thickness direction; a step of forming a conductor layer on a one-side surface of the base insulating layer in the thickness direction; and a step of heating the metal support substrate and/or the conductor layer, wherein the metal support substrate and/or the conductor layer contain(s) a copper alloy, wherein the copper alloy contains: a first metal consisting of copper; and a second metal that can be alloyed with the copper, and wherein a heating temperature in the heating is 350° C. or more.

In the method of producing the wiring circuit board of the above-described [6], the metal support substrate and/or the conductor layer contain(s) a copper alloy, and the metal support substrate and/or the conductor layer are/is heated at a predetermined heating temperature. Therefore, according to the above-described method of producing the wiring circuit board, the above-described sea-island structure can be favorably formed. As a result, according to the above-described method of producing the wiring circuit board, a wiring circuit board having both excellent mechanical strength and excellent conductivity can be efficiently obtained.

EFFECTS OF THE INVENTION In the wiring circuit board of the present invention, the metal support substrate and/or the conductor layer contain(s) a copper alloy, and the copper alloy contains a first metal consisting of copper and a second metal that can be alloyed with copper. Therefore, the above-described wiring circuit board has excellent mechanical strength.

The above-described copper alloy has a sea-island structure, and the sea-island structure includes a sea portion having a continuous shape and an island portion having a discontinuous shape. Therefore, the above-described wiring circuit board has excellent conductivity derived from the sea-island structure.

As a result, the above-described wiring circuit board has both excellent mechanical strength and excellent conductivity.

Further, in the method of producing the wiring circuit board of the present invention, the metal support substrate and/or the conductor layer contain(s) a copper alloy, and the metal support substrate and/or the conductor layer are/is heated at a predetermined heating temperature. Therefore, according to the method of producing the wiring circuit board, the above-described sea-island structure can be favorably formed. As a result, according to the above-described method of producing the wiring circuit board, a wiring circuit board having both excellent mechanical strength and excellent conductivity can be efficiently obtained.

### BRIEF DESCRIPTION OF THE DRAWINGS

FIG. 1 is a cross-sectional view of one embodiment of the wiring circuit board of the present invention.

FIG. 2A shows a step of preparing a metal support substrate, FIG. 2B shows a step of heating the metal support substrate, FIG. 2C shows a step of forming a base insulating layer on the one-side surface of the metal support substrate in the thickness direction, FIG. 2D shows a step of forming a conductor layer on the one-side surface of the base insulating layer in the thickness direction, and FIG. 2E shows a step of forming a cover insulating layer on the one-side surface of the base insulating layer in the thickness direction and the conductor layer.

FIG. 3 shows SEM images of Reference Comparative Example 1 and Reference Example 1.

FIG. 4 shows EDX images of Reference Comparative Example 1 and Reference Example 1.

FIG. 5 shows an XRD chart of Reference Comparative Example 1 and Reference Example 1.

### DESCRIPTION OF THE EMBODIMENT

### 1. Wiring Circuit Board

### (1) Entire Structure

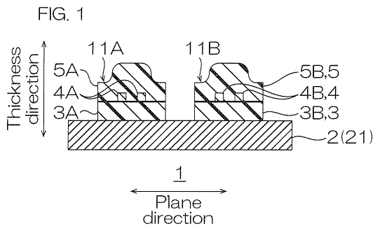

Hereinafter, one embodiment of a wiring circuit board of the present invention is described with reference to FIG. 1.

In FIG. 1, a wiring circuit board 1 has a thickness. The wiring circuit board 1 extends in a plane direction. The plane direction is orthogonal to a thickness direction. The wiring circuit board 1 has a plate shape. The thickness of the wiring circuit board 1 is, for example, 10 μm or more. The thickness of the wiring circuit board 1 is, for example, 500 μm or less, preferably 300 μm or less, and more preferably 200μm or less.

In FIG. 1, the wiring circuit board 1 includes a metal support substrate 2, a base insulating layer 3 disposed on a one-side surface of the metal support substrate 2 in the thickness direction, a conductor layer 4 disposed on a one-side surface of the base insulating layer 3 in the thickness direction, and a cover insulating layer 5 disposed on the one-side surface of the base insulating layer 3 in the thickness direction so as to cover the conductor layer 4.

The wiring circuit board 1 includes a plurality of divided bodies 11A and 11B. Each of the divided bodies 11A and 11B is disposed on one side of the metal support substrate 2 in the thickness direction. The divided bodies 11A and 11B are divided in the plane direction. The divided body 11B is spaced apart from the divided body 11A in the plane direction. The divided body 11A includes a base insulating layer 3A, a conductor layer 4A, and a cover insulating layer 5A. The divided body 11B includes a base insulating layer 3B, a conductor layer 4B, and a cover insulating layer 5B.

### (2) Metal Support Substrate

The metal support substrate 2 is disposed in the other end portion of the wiring circuit board 1 in the thickness direction. The metal support substrate 2 forms the other end surface of the wiring circuit board 1 in the thickness direction. The metal support substrate 2 extends in the plane direction. Each of a one-side surface and an other-side surface of the metal support substrate 2 in the thickness direction is a flat surface. The metal support substrate 2 is in contact with the other-side surfaces of the divided bodies 11A and 11B in the thickness direction.

The metal support substrate 2 consists of, for example, metal, and preferably consists of a rolled metal (hereinafter referred to as a rolled metal). Examples of the metal include a copper alloy. That is, the metal support substrate 2 contains a copper alloy, and preferably consists of a copper alloy. The details of the copper alloy are described later.

The metal support substrate 2 is relatively thin. The metal support substrate 2 has a thickness of, for example, 250 μm or less, preferably 225 μm or less, and more preferably 200 μm or less. Furthermore, the thickness of the metal support substrate 2 is usually 25 μm or more. That is, the thickness of the metal support substrate 2 is, for example, 25 μm or more and 250 μm or less, preferably 25μm or more and 225 μm or less, and more preferably 25 μm or more and 200 μm or less.

### (3) Base Insulating Layer

The base insulating layer 3 is disposed on the one-side surface of the metal support substrate 2 in the thickness direction. The base insulating layer 3 extends in the plane direction. The one-side surface of the base insulating layer 3 in the thickness direction is a flat surface.

The base insulating layer 3 has a pattern shape. Specifically, the base insulating layer 3 includes a plurality of base insulating layers 3A and 3B. The base insulating layers 3A and 3B are included in the above-described divided bodies 11A and 11B, respectively.

Examples of the material of the base insulating layer 3 include resin. That is, the base insulating layer 3 preferably consists of a resin. Examples of the resin include a polyimide resin, a polyamide-imide resin, an acrylic resin, a polyether nitrile resin, a polyether sulfone resin, a polyethylene terephthalate resin, a polyethylene naphthalate resin, and a polyvinyl chloride resin, and preferably a polyimide resin is used. That is, the above-described resin is preferably a polyimide resin.

The base insulating layer 3 is formed, for example, by thermally curing the above-described resin. The details of the thermally curing of the resin are described later.

The base insulating layer 3 has a thickness of, for example, 1 μm or more, preferably 3 μm or more. Furthermore, the thickness of the base insulating layer 3 is, for example, 30μm or less, preferably 20 μm or less.

### (4) Conductor Layer

The conductor layer 4 is disposed on the one-side surface of the base insulating layer 3 in the thickness direction. The conductor layer 4 extends in the plane direction. In the present embodiment, the conductor layer 4 has a substantially rectangular shape in a cross-sectional view. A one-side surface of the conductor layer 4 in the thickness direction is a flat surface.

The conductor layer 4 includes a plurality of wires and terminal portions. The wires may be a clock wiring, a differential wiring, or another wiring. In the present embodiment, the wires are a differential wiring. The differential wiring is a pair wiring including a pair (that is, two) of signal wires. The signal wires are arranged substantially parallel to each other to form one signal transmission line. The terminal portions are formed at both end portions of each wire in a longitudinal direction. The wires and the terminal portions are disposed on the one-side surface of each of the base insulating layers 3A and 3B in the thickness direction.

Examples of the material of the conductor layer 4 include a conductive metal, and specifically include copper and a copper alloy (described later), and preferably copper is used.

Further, the terminal portions (not shown) are plated by a known method if necessary, and is thermally treated if necessary. Details of the thermal treatment are described later.

### (5) Cover Insulating Layer

The cover insulating layer 5 is disposed on the one-side surface of the base insulating layer 3 in the thickness direction so as to cover the conductor layer 4. The cover insulating layer 5 forms a one-side surface of the wiring circuit board 1 in the thickness direction. The cover insulating layer 5 extends in the plane direction.

The cover insulating layer 5 has a pattern shape. Specifically, the cover insulating layer 5 includes a plurality of cover insulating layers 5A and 5B. The cover insulating layers 5A and 5B are included in the above-described divided bodies 11A and 11B, respectively. The cover insulating layers 5A and 5B are disposed on the one-side surfaces of the base insulating layers 3A and 3B, respectively, so as to cover the wires of the conductor layer 4.

In the present embodiment, an end surface of the cover insulating layer 5 (each of the cover insulating layers 5A and 5B) in a width direction is flush with an end surface of the base insulating layer 3 (each of the base insulating layers 3A and 3B) in the width direction.

Examples of the material of the cover insulating layer 5 include the same resins as those cited as examples of the material of the base insulating layer 3. That is, the cover insulating layer 5 preferably consists of a resin. Examples of the resin include a polyimide resin, a polyamide-imide resin, an acrylic resin, a polyether nitrile resin, a polyether sulfone resin, a polyethylene terephthalate resin, a polyethylene naphthalate resin, and a polyvinyl chloride resin, and preferably a polyimide resin is used. That is, the above-described resin is preferably a polyimide resin.

The cover insulating layer 5 is formed, for example, by thermally curing the above-described resin. The details of the thermally curing of the resin are described later.

The cover insulating layer 5 has a thickness of, for example, 1 μm or more, preferably 3 μm or more. The thickness of the cover insulating layer 5 is, for example, 30μm or less, preferably 20μm or less.

The thickness of the cover insulating layer 5 is a length in the thickness direction between the one-side surface of the base insulating layer 3 in the thickness direction and the one-side surface of the cover insulating layer 5 in the thickness direction, which faces the above-described one-side surface of the base insulating layer 3 without the conductor layer 4 therebetween.

The total of the thickness of the cover insulating layer 5 and the thickness of the base insulating layer 3 is, for example, 80 μm or less, preferably 50 μm or less, and more preferably 40 μm or less. The total of the thickness of the cover insulating layer 5 and the thickness of the base insulating layer 3 is, for example, 5 μm or more.

### 2. Copper Alloy

### (1) Entire Structure

In the above-described wiring circuit board 1, the metal support substrate 2 contains a copper alloy, and preferably consists of a copper alloy.

The copper alloy is an alloy containing copper. The copper alloy contains a first metal consisting of copper and a second metal that can be alloyed with copper. The phrase “can be alloyed” indicates that it can form an alloy. The alloy may be a solid solution, a eutectic, an intermetallic compound, or a complex thereof.

In the copper alloy, the second metal is an additive metal added to the copper that is the first metal. That is, the second metal represents a metal other than copper. Examples of the second metal include titanium, nickel, silicon, and iron. These may be used alone or in combination of two or more. That is, the copper alloy may be a two-component alloy or an alloy of three or more components.

The second metal is preferably titanium. When the second metal is titanium, the copper alloy is a copper-titanium alloy. When a copper-titanium alloy is used, the wiring circuit board 1 has more excellent mechanical strength.

In the copper alloy, the content ratio of the first metal (that is, copper (the same applies hereinafter)) and the content ratio of the second metal (preferably titanium (the same applies hereinafter)) are appropriately set depending on the purpose and use.

More specifically, the atomic ratio of the first metal is, for example, 50 to 99 atomic %, preferably 80 to 99 atomic %, and more preferably 90 to 99 atomic % with respect to the total amount (total number of atoms) of the copper alloy.

Furthermore, the atomic ratio of the second metal is, for example, 1 to 50 atomic %, preferably 1 to 20 atomic %, and more preferably 1 to 10 atomic % with respect to the total amount (total number of atoms) of the copper alloy.

In the copper alloy, the sum of the atomic ratio of the first metal and the atomic ratio of the second metal is, for example, 100 atomic %.

On the basis of mass, the mass ratio of the first metal is, for example, 50 to 99% by mass, preferably 80 to 99% by mass, and more preferably 90 to 99% by mass with respect to the total amount (total mass) of the copper alloy.

Furthermore, on the basis of mass, the mass ratio of the second metal is, for example, 1 to 50% by mass, preferably 1 to 20% by mass, and more preferably 1 to 10% by mass with respect to the total amount (total mass) of the copper alloy.

In the copper alloy, the sum of the mass ratio of the first metal and the mass ratio of the second metal is, for example, 100% by mass.

### (2) Phase Separation Structure

In the metal support substrate 2, the copper alloy has a phase-separation structure. Examples of the phase-separation structure include a sea-island structure and a lamellar structure (described below). In the metal support substrate 2, the copper alloy has at least a sea-island structure. In the metal support substrate 2, preferably the copper alloy does not have a lamellar structure (described below), and has a sea-island structure. Particularly preferably, in the metal support substrate 2, the entire copper alloy has a sea-island structure.

### Sea-Island Structure

The sea-island structure includes a sea portion having a continuous shape (i.e., a sea phase) and an island portion having a discontinuous shape (i.e., an island phase).

More specifically, the copper alloy having a sea-island structure includes a sea portion containing the first metal in a relatively high content ratio and the second metal in a relatively low content ratio, and an island portion containing the first metal in a relatively low content ratio and the second metal in a relatively high content ratio.

The sea portion and island portion are phase-separated, and the island portion is disposed so as to be dispersed in a matrix consisting of the sea portion.

The presence of the sea-island structure can be confirmed, for example, by the following method. That is, for example, the presence of the sea-island structure can be confirmed by analyzing a cross section of the copper alloy by an energy dispersive X-ray spectroscopy (EDX spectroscopy) and observing the distribution of the first metal and the distribution of the second metal. Furthermore, for example, the presence of the sea-island structure can be confirmed by photographing a cross section of the copper alloy with a scanning electron microscope (SEM), and observing the sea portion and the island portion in the image (SEM image). Preferably, a sea-island structure is confirmed by energy-dispersive X-ray spectroscopy (EDX spectroscopy).

The content ratios of the first metal are different from each other in the sea portion and the island portion. More specifically, the content ratio of the first metal in the sea portion is higher than the content ratio of the first metal in the island portion. Furthermore, the content ratios of the second metal are different from each other in the sea portion and the island portion. More specifically, the content ratio of the second metal in the sea portion is lower than the content ratio of the second metal in the island portion.

For example, on the atomic basis, the atomic ratio of the first metal in the sea portion is, for example, 50 to 100 atomic %, preferably 80 to 100 atomic %, and more preferably 90 to 100 atomic % with respect to the total amount (total number of atoms) of the copper alloy.

The atomic ratio of the second metal in the sea portion is, for example, 0 to 50 atomic %, preferably 0 to 20 atomic %, and more preferably 0 to 10 atomic % with respect to the total amount (total number of atoms) of the copper alloy.

The sum of the atomic ratio of the first metal in the sea portion and the atomic ratio of the second metal in the sea portion is, for example, 100 atomic %.

On the other hand, the atomic ratio of the first metal in the island portion is, for example, 50 to 99 atomic %, preferably 60 to 99 atomic %, and more preferably 70 to 99 atomic % with respect to the total amount (total number of atoms) of the copper alloy.

Furthermore, the atomic ratio of the second metal in the island portion is, for example, 1 to 50 atomic %, preferably 1 to 40 atomic %, and more preferably 1 to 30 atomic % with respect to the total amount (total number of atoms) of the copper alloy.

The sum of the atomic ratio of the first metal in the island portion and the atomic ratio of the second metal in the island portion is, for example, 100 atomic %.

From the viewpoint of the conductivity, with respect to the atomic ratio of the first metal in the island portion, the atomic ratio of the first metal in the sea portion is, for example, 1.01 times or more, preferably 1.05 times or more, and more preferably 1.1 times or more.

Furthermore, with respect to the atomic ratio of the first metal in the island portion, the atomic ratio of the first metal in the sea portion is, for example, 5 times or less.

That is, with respect to the atomic ratio of the first metal in the island portion, the atomic ratio of the first metal in the sea portion is, for example, 1.01 times or more and 5 times or less, preferably 1.05 times or more and 5 times or less, more preferably 1.1 times or more and 5 times or less.

Furthermore, from the viewpoint of the conductivity, with respect to the atomic ratio of the second metal in the island portion, the atomic ratio of the second metal in the sea portion is, for example, 0 times or more. Furthermore, with respect to the atomic ratio of the second metal in the island portion, the atomic ratio of the second metal in the sea portion is, for example, 0.9 times or less, preferably 0.8 times or less, more preferably 0.5 times or less.

That is, with respect to the atomic ratio of the second metal in the island portion, the atomic ratio of the second metal in the sea portion is, for example, 0 times or more and 0.9 times or less, preferably 0 times or more and 0.8 times or less, more preferably 0 times or more and 0.5 times or less.

On the basis of mass, the mass ratio of the first metal in the sea portion is, for example, 50 to 100% by mass, preferably 80 to 100% by mass, and more preferably 90 to 100% by mass with respect to the total amount (total mass) of the copper alloy.

The content ratio of the second metal in the sea portion is, for example, 0 to 50% by mass, preferably 0 to 20% by mass, and more preferably 0 to 10% by mass with respect to the total amount (total mass) of the copper alloy.

The sum of the mass ratio of the first metal in the sea portion and the mass ratio of the second metal in the sea portion is, for example, 100% by mass.

The mass ratio of the first metal in the island portion is, for example, 50 to 99% by mass, preferably 75 to 99% by mass, and more preferably 80 to 99% by mass with respect to the total amount (total mass) of the copper alloy.

The content ratio of the second metal in the island portion is, for example, 1 to 50% by mass, preferably 1 to 25% by mass, and more preferably 1 to 20% by mass with respect to the total amount (total mass) of the copper alloy.

The sum of the mass ratio of the first metal in the island portion and the mass ratio of the second metal in the island portion is, for example, 100% by mass.

With respect to the mass ratio of the first metal in the island portion, the mass ratio of the first metal in the sea portion is, for example, 1.01 times or more, preferably 1.05 times or more, more preferably 1.1 times or more. Furthermore, with respect to the mass ratio of the first metal in the island portion, the mass ratio of the first metal in the sea portion is, for example, 5 times or less.

That is, with respect to the mass ratio of the first metal in the island portion, the mass ratio of the first metal in the sea portion is, for example, 1.01 times or more and 5 times or less, preferably 1.05 times or more and 5 times or less, more preferably 1.1 times or more and 5 times or less.

Furthermore, with respect to the mass ratio of the second metal in the island portion, the mass ratio of the second metal in the sea portion is, for example, 0 times or more. Furthermore, with respect to the mass ratio of the second metal in the island portion, the mass ratio of the second metal in the sea portion is, for example, 0.9 times or less, preferably 0.8 times or less, more preferably 0.5 times or less.

That is, with respect to the mass ratio of the second metal in the island portion, the mass ratio of the second metal in the sea portion is, for example, 0 times or more and 0.9 times or less, preferably 0 times or more and 0.8 times or less, more preferably 0 times or more and 0.5 times or less.

The atomic ratios and the mass ratios are measured by a known method. Examples of the measuring method include energy dispersive X-ray spectroscopy (EDX spectroscopy), fluorescent X-ray spectroscopy, inductively coupled plasma optical emission spectrometry, and glow discharge optical emission spectrometry, and preferably energy dispersive X-ray spectroscopy (EDX spectroscopy) is used.

Furthermore, the atomic ratio is measured, and then the mass ratio can be calculated based on the atomic ratio. Furthermore, the mass ratio is measured, and then the atomic ratio can be calculated based on the mass ratio.

In the sea-island structure, the island portion has a number-average particle diameter of, for example, 50 nm or more, preferably 100 nm or more, more preferably 200 nm or more, even more preferably 220 nm or more. In the sea-island structure, the number-average particle diameter of the island portion is, for example, 5000 nm or less, preferably 2000 nm or less, more preferably 1000 nm or less. That is, the number-average particle diameter of the island portion is, for example, 50 nm or more and 5000 nm or less, preferably 100 nm or more and 2000nm, more preferably 200 nm or more and 1000 nm or less, even more preferably 220 nm or more and 1000 nm or less.

The number-average particle diameter of the island portion is measured using a scanning electron microscope (SEM) according to Examples described below. More specifically, in the image of a cross section of a copper alloy (hereinafter referred to as SEM image) captured by a scanning electron microscope (SEM), the diameters of ten or more islands of the island portion are measured, and the average thereof is calculated as the number-average particle diameter.

The copper alloy having a sea-island structure preferably has Cu₃Ti and/or Cu₄Ti. In such a case, in the XRD chart obtained by measuring the X-ray diffraction (XRD) of the copper alloy, a peak having a peak top in a range of 2θ values (that is, diffraction angles) of 41.00° or more to 42.00° or less is confirmed as a peak derived from Cu₃Ti and/or Cu₄Ti. A copper alloy having such a peak has a particularly excellent sea-island structure. Thus, the above-described wiring circuit board 1 has preferably both excellent mechanical strength and excellent conductivity.

The X-ray diffraction of the copper alloy is measured in conformity with Examples described below.

Such a sea-island structure is formed, for example, by heating a copper alloy having a lamellar structure. The details of the heating are described later.

### (3) Physical Properties

The copper alloy has relatively high mechanical strength. The above-described copper alloy has a tensile strength of, for example, 500 MPa or more, preferably 800 MPa or more. The tensile strength of the above-described copper alloy is, for example, 2000 MPa or less, preferably 1500 MPa or less. That is, the tensile strength of the copper alloy is, for example, 500 MPa or more and 2000 MPa or less, preferably 800 MPa or more and 1500 MPa or less. The tensile strength of the copper alloy is measured in conformity with JIS Z2241 (2011).

Furthermore, the above-described copper alloy has relatively high conductivity. For example, when the copper alloy is rolled, the conductivity of the copper alloy at 20° C. is, for example, 50% IACS or less, preferably 40% IACS or less in a rolling direction (MD direction). The conductivity of the copper alloy at 20° C. is, for example, 1% IACS or more, preferably 5% IACS or more in the rolling direction (MD direction). That is, the conductivity of the copper alloy at 20° C. is, for example, 1% IACS or more and 50% IACS or less, preferably 5% IACS or more and 40% IACS or less in the rolling direction (MD direction).

When the copper alloy is rolled, the conductivity of the copper alloy at 20° C. is, for example, 50% IACS or less, preferably 40% IACS or less in a direction (TD direction) perpendicular to the rolling direction. The conductivity of the copper alloy at 20° C. is, for example, 1% IACS or more, preferably 5% IACS or more in the direction (TD direction) perpendicular to the rolling direction. That is, the conductivity of the copper alloy at 20° C. is, for example, 1% IACS or more and 50% IACS or less, preferably 5% IACS or more and 40% IACS or less in the direction (TD direction) perpendicular to the rolling direction.

IACS represents International Annealed Copper Standard, and the conductivity is measured in conformity with JIS H0505 (1975).

### 3. Method of Producing Wiring Circuit Board

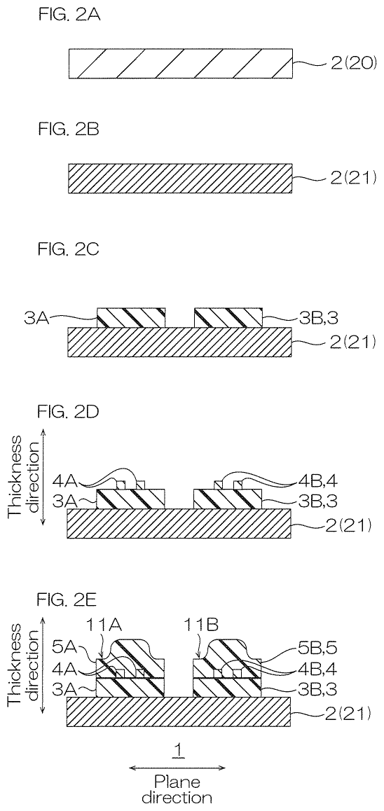

Hereinafter, one embodiment of a method of producing the wiring circuit board of the present invention is described with reference to FIG. 2.

### (1) Metal Support Substrate

In the production of the circuit board 1, first, a metal support substrate 2 is prepared as shown in FIGS. 2A and 2B.

More specifically, in this step, the metal support substrate 2 which is yet to be heated (described later) is first prepared as shown in FIG. 2A. Hereinafter, the metal support substrate 2 that is yet to be heated (described later) is referred to as an original sheet 20. The original sheet 20 is available, for example, as a commercial product. The original sheet 20 is, for example, a rolled copper alloy. Furthermore, the original sheet 20 consists of, for example, a copper alloy having a lamellar structure.

Next, in this method, the original sheet 20 is heated (preheated) to obtain a heated metal support substrate 2, as shown in FIG. 2B. That is, in the present embodiment, the step of preparing the metal support substrate 2 includes a step of heating the original sheet 20.

Hereinafter, the heated metal support substrate 2 is referred to as a heated substrate 21. The details of the heating are described later.

### (2) Base Insulating Layer

Next, in this method, a base insulating layer 3 is formed on a one-side surface of the metal support substrate 2 (preferably the heated substrate 21) in the thickness direction, as shown in FIG. 2C.

The method of forming the base insulating layer 3 is not particularly limited. For example, a varnish is first prepared. The varnish contains, for example, a photosensitizer, a resin component, and a solvent. When the base insulating layer 3 consists of a polyimide resin, the resin component preferably contains an acid dianhydride and a diamine.

Next, in this method, the above-described varnish is applied to the one-side surface of the metal support substrate 2 in the thickness direction, and dried by heating to form a photosensitive coating film. The coating film contains a polyamic acid resin. The polyamic acid resin is a reaction product of an acid dianhydride and a diamine, and is a precursor of a polyimide resin.

In the step of forming a base insulating layer 3, the drying temperature is, for example, 50° C. or more. Furthermore, in the step of forming a base insulating layer 3, the drying temperature is, for example, 200° C. or less. That is, the drying temperature is, for example, 50° C. or more and 200° C. or less.

In the step of forming a base insulating layer 3, the drying time is, for example, 1 minute or more. Furthermore, in the step of forming a base insulating layer 3, the drying time is, for example, 1 hour or less. That is, the drying time is, for example, 1 minute or more and 1 hour or less.

Next, in this method, the above-described coating film is exposed to light and developed to form the coating film into a predetermined pattern. Next, in this method, the coating film in the predetermined pattern (that is, a precursor of a resin) is thermally cured by heating to obtain a base insulating layer 3.

In the step of forming a base insulating layer 3, the thermally curing temperature is, for example, 100° C. or more, preferably 200° C. or more. Furthermore, in the step of forming a base insulating layer 3, the thermally curing temperature is, for example, 500° C. or less, preferably 450° C. or less. That is, the thermally curing temperature is, for example, 100° C. or more and 500° C. or less, preferably 200° C. or more and 450° C. or less.

In the step of forming a base insulating layer 3, the thermally curing time is, for example, 1 hour or more. Furthermore, in the step of forming a base insulating layer 3, the thermally curing time is, for example, 10 hours or less. That is, the thermal curing time is, for example, 1 hour or more and 10 hours or less.

As described above, the base insulating layer 3 is disposed on the one-side surface of the metal support substrate 2 in the thickness direction.

### (3) Conductor Layer

Next, in this method, a conductor layer 4 is formed on a one-side surface of the base-insulating layer 3 in the thickness direction, as shown in FIG. 2D.

The method of forming the conductor layer 4 is not particularly limited, and a known conductor pattern forming method is employed. Examples of the conductor pattern forming method include an additive method, a semi-additive method, and a subtractive method, and preferably an additive method is used.

Furthermore, in this method, although not shown, if necessary, the terminal portions of the conductor layer 4 may be plated, or the conductor layer 4 may be thermally treated.

As described above, a conductor layer 4 is disposed on the one-side surface of the base insulating layer 3 in the thickness direction.

### (4) Cover Insulating Layer

Then, as shown in FIG. 2E, in this method, a cover insulating layer 5 is formed on the one-side surface of the base insulating layer 3 and the conductor layer 4.

The method of forming the cover insulating layer 5 is not particularly limited. For example, the cover insulating layer 5 is formed by the same method as the method of forming the base insulating layer 3.

More specifically, for example, a varnish is first prepared. The varnish contains, for example, a photosensitizer, a resin component, and a solvent. When the cover insulating layer 5 consists of a polyimide resin, the resin component preferably contains an acid dianhydride and a diamine.

Next, in this method, the above-described varnish is applied to the one-side surface of the base insulating layer 3 in the thickness direction and the conductor layer 4 in the thickness direction, and dried by heating to form a photosensitive coating film. The coating film contains a polyamic acid resin. The polyamic acid resin is a reaction product of an acid dianhydride and a diamine, and is a precursor of a polyimide resin.

In the step of forming a cover insulating layer 5, the drying temperature is, for example, 50° C. or more. Furthermore, in the step of forming a cover insulating layer 5, the drying temperature is, for example, 200° C. or less. That is, the drying temperature is, for example, 50° C. or more and 200° C. or less.

In the step of forming a cover insulating layer 5, the drying time is, for example, 1 minute or more. Furthermore, in the step of forming a cover insulating layer 5, the drying time is, for example, 1 hour or less. That is, the drying time is, for example, 1 minute or more and 1 hour or less.

Then, in this method, the above-described coating film is exposed to light and developed to form the coating film into a predetermined pattern. Then, in this method, the coating film in the predetermined pattern (that is, a precursor of a resin) is thermally cured by heating to obtain a cover insulating layer 5.

In the step of forming a cover insulating layer 5, the thermally curing temperature is, for example, 100° C. or more, preferably 200° C. or more. Furthermore, in the step of forming a cover insulating layer 5, the thermally curing temperature is, for example, 500° C. or less, preferably 450° C. or less. That is, the thermally curing temperature is, for example, 100° C. or more and 500° C. or less, preferably 200° C. or more and 450° C. or less.

In the step of forming a cover insulating layer 5, the thermally curing time is, for example, 1 hour or more. Furthermore, in the step of forming a cover insulating layer 5, the thermally curing time is, for example, 10 hours or less. That is, the thermal curing time is, for example, 1 hour or more and 10 hours or less.

As described above, the cover insulating layer 5 is disposed on the one-side surface of the base insulating layer 3 in the thickness direction and the conductor layer 4 in the thickness direction. More specifically, on the one-side surface of the base insulating layer 3 in the thickness direction, the cover insulating layer 5 covers the wire of the conductor layer 4 and exposes a terminal portion (not shown).

Furthermore, in each of the above-described steps, the metal support substrate 2, the base insulating layer 3, the conductor layer 4, and the cover insulating layer 5 are aligned with each other to produce a wiring circuit board 1 (see FIG. 1).

### 4. Heating

In the above-described method of producing the wiring circuit board 1, the original sheet 20 is heated to obtain a heated substrate 21.

The original sheet 20 is, for example, a rolled copper alloy as described above. Further, in the original sheet 20, the copper alloy has a lamellar structure. In the original sheet 20, the copper alloy preferably does not have the above-described sea-island structure. Particularly preferably, in the original sheet 20, the entire copper alloy has the lamellar structure.

The lamellar structure includes a first phase having a nano-order thin layer shape and a second phase having a nano-order thin layer shape.

More specifically, the copper alloy having a lamellar structure includes a first phase containing the first metal in a relatively high content ratio and the second metal in a relatively low content ratio, and a second phase containing the first metal in a relatively low content ratio and the second metal in a relatively high content ratio.

The first phase and the second phase are phase-separated and disposed so as to be alternately laminated.

The presence of the lamellar structure can be confirmed, for example, by the following method. That is, for example, the presence of the lamellar structure can be confirmed by photographing a cross section of the copper alloy with a scanning electron microscope (SEM), and observing the first phase and the second phase in the image (SEM image). Furthermore, for example, the presence of the lamellar structure can be confirmed by analyzing a cross section of the copper alloy by an energy dispersive X-ray spectroscopy (EDX spectroscopy) and observing the distribution of the first metal and the distribution of the second metal. Preferably, the presence of the lamellar structure is confirmed by imaging with a scanning electron microscope.

The content ratios of the first metal are different from each other in the first phase and the second phase. More specifically, the content ratio of the first metal in the first phase is higher than the content ratio of the first metal in the second phase. The content ratios of the second metal are different from each other in the first phase and the second phase. More specifically, the content ratio of the second metal in the first phase is lower than the content ratio of the second metal in the second phase.

In the lamellar structure, the first phase has a thickness of, for example, 10 nm or more and 100 nm or less. In the lamellar structure, the second phase has a thickness of, for example, 5 nm or more and 100 nm or less. The thickness of the first phase and the thickness of the second phase are measured by photographing a cross section of the copper alloy having a lamellar structure with a scanning electron microscope (SEM) and observing the image.

The copper alloy having a lamellar structure is formed, for example, by rolling the copper alloy. The conditions for rolling the copper alloy are appropriately set in a range in which the above-described lamellar structure is obtained.

Then, in the above-described method of producing the wiring circuit board 1, the original sheet 20 having a lamellar structure is heated. The heating method is not particularly limited. For example, although not shown, the original sheet 20 can be heated by winding the original sheet 20 around a thermal treatment core and placing the original sheet 20 wound around the thermal treatment core in a heating furnace.

In the heating, the heating conditions are adjusted so that a copper alloy having the above-described sea-island structure is obtained.

More specifically, the heating temperature in the above-described heating is 350° C. or more, preferably 360° C. or more. Furthermore, the heating temperature in the heating is, for example, 500° C. or less, preferably 450° C. or less. That is, the heating temperature in the heating is, for example, 350° C. or more and 500° C. or less, preferably 360° C. or more and 450° C. or less.

The heating time in the above-described heating is adjusted in accordance with the heating temperature, but is, for example, 3 minutes or more. Furthermore, the heating time in the heating is, for example, 10 hours or less. That is, the heating time in the heating is, for example, 3 minutes or more and 10 hours or less.

Uneven distribution and grain growth of the second metal in the entire copper alloy can be caused by the above-described heating. As a result, a copper alloy having a sea-island structure is formed.

More specifically, when the original sheet 20 is heated under the above-described predetermined conditions, the second metal is unevenly distributed in the entire copper alloy. That is, by the above-described heating, in the copper alloy, an island portion containing the first metal in a relatively low content ratio and the second metal in a relatively high content ratio is formed. Further, by the above-described heating, a sea portion containing the first metal in a relatively high content ratio and the second metal in a relatively low content ratio is formed. Further, in the copper alloy, the island portion is disposed so as to be dispersed in the sea portion. That is, the above-described sea-island structure is formed by the above-described heating.

Consequently, a copper alloy having the above-described sea-island structure is obtained as a heated substrate 21.

In other words, the heated substrate 21 contains a copper alloy having the sea-island structure, and preferably consists of a copper alloy having the sea-island structure. As described above, the heated substrate 21 is provided as a metal support substrate 2 for producing the wiring circuit board 1.

### 5. Operations and Effects

In the above-described wiring circuit board 1, the metal support substrate 2 contains a copper alloy, and the copper alloy contains a first metal consisting of copper and a second metal that can be alloyed with copper. Therefore, the above-described wiring circuit board 1 has excellent mechanical strength.

The above-described copper alloy has a sea-island structure, and the sea-island structure includes a sea portion having a continuous shape and an island portion having a discontinuous shape. Therefore, the above-described wiring circuit board 1 has excellent conductivity derived from the sea-island structure.

Consequently, the above-described wiring circuit board 1 has both excellent mechanical strength and excellent conductivity.

Furthermore, in the above-described wiring circuit board 1, when the atomic ratio of the second metal in the sea portion is the above-described predetermined value or less with respect to the atomic ratio of the second metal in the island portion, the above-described wiring circuit board has more excellent conductivity. That is, when the atomic ratio of copper is relatively high in the sea portion having a continuous shape, the above-described wiring circuit board has more excellent conductivity.

Furthermore, in the above-described wiring circuit board 1, when the second metal is titanium and the copper alloy is a copper-titanium alloy, the above-described wiring circuit board has more excellent mechanical strength.

Furthermore, in the above-described wiring circuit board, the number-average particle diameter of the island portion is a predetermined value or more. That is, in the above-described wiring circuit board 1, the copper alloy has a particularly excellent sea-island structure. Therefore, the above-described wiring circuit board 1 has excellent mechanical strength and excellent conductivity.

Furthermore, in the above-described wiring circuit board 1, when the X-ray diffraction (XRD) of the copper alloy is measured, a peak having a peak top in a range of 2θ values of 41.00° or more to 42.00° or less is confirmed in the XRD chart. Such a copper alloy has a particularly excellent sea-island structure.

Thus, the above-described wiring circuit board 1 has both excellent mechanical strength and excellent conductivity.

In the method of producing the above-described wiring circuit board, the metal support substrate 2 contains a copper alloy, and the metal support substrate 2 is heated at a predetermined heating temperature. Therefore, according to the method of producing the above-described wiring circuit board, the above-described sea-island structure can be suitably formed. As a result, according to the method of producing the above-described wiring circuit board, a wiring circuit board 1 having both excellent mechanical strength and excellent conductivity can be efficiently obtained.

### 6. Modified Examples

In the modified examples, the same members and steps as in one embodiment are given the same numerical references, and the descriptions thereof are omitted. Further, each modified example can achieve the same operations and effects as that of one embodiment unless otherwise specified. Furthermore, one embodiment and each modified example can be appropriately combined.

In the above-described embodiment, the original sheet 20 is heated by winding the original sheet 20 around the thermal treatment core and placing the original sheet 20 wound around the thermal treatment core in a heating furnace. However, the heating method is not limited to the above. For example, the original sheet 20 may be thermally treated by allowing the original sheet 20 to pass through a heating furnace while conveying it by a roll-to-roll method. The heating conditions are the same as described above.

Furthermore, in the above-described embodiment, to form the heated substrate 21 (i.e., a copper alloy having a sea-island structure), the original sheet 20 (i.e., a copper alloy having a lamellar structure) is heated before the base insulating layer 3 is formed. However, the timing of the heating is not limited to the above.

For example, in the production of the wiring circuit board 1, the varnish is heated in the step of forming a base insulating layer 3. At this time, the metal support substrate 2 is heated together with the varnish. Therefore, for example, without heating the original sheet 20 before a base insulating layer 3 is formed, the original sheet 20 may be heated in the step of forming a base insulating layer 3. More specifically, a varnish as the material of the base insulating layer 3 is applied to the original sheet 20, and thereafter the varnish is heated to form the base insulating layer 3. At this time, a heated substrate 21 (i.e., a copper alloy having the above-described sea-island structure) can be formed by heating the original sheet 20 together with the varnish under the above-described conditions.

Furthermore, for example, in the production of the wiring circuit board 1, in the step of forming a conductor layer 4, if necessary, the conductor layer 4 may be heated in a thermal treatment. Also in such a case, a heated substrate 21 (i.e., a copper alloy having the above-described sea-island structure) can be formed by heating the original sheet 20 together with the conductor layer 4 under the above-described conditions.

Furthermore, for example, in the production of the wiring circuit board 1, the varnish is heated in the step of forming a cover insulating layer 5. Therefore, for example, a copper alloy having the above-described sea-island structure can be formed by heating the original sheet 20 in the step of forming a cover insulating layer 5.

More specifically, the base insulating layer 3 is laminated on the original sheet 20, and further the conductor layer 4 is laminated on the base insulating layer 3. Next, a varnish as the material of the cover insulating layer 5 is applied to the base insulating layer 3 and the conductor layer 4, and then the varnish is heated to form the cover insulating layer 5. At this time, a heated substrate 21 (i.e., a copper alloy having the above-described sea-island structure) can be formed by heating the original sheet 20 together with the varnish under the above-described conditions.

That is, the heating of the original sheet 20 may be carried out before the step of forming a base insulating layer 3, may be carried out in the step of forming a base insulating layer 3, may be carried out in the step of forming a conductor layer 4, or may be carried out in the step of forming a cover insulating layer 5. Furthermore, these may be combined. The heating of the original sheet 20 is carried out before the step of forming a base insulating layer 3.

Furthermore, in the above-described embodiment, the conductor layer 4 contains copper (i.e., copper that is not alloyed). However, for example, the conductor layer 4 may contain a copper alloy having the above-described sea-island structure.

In such a case, for example, the conductor layer 4 containing a copper alloy having the above-described sea-island structure can be formed by forming a conductor layer 4 containing a copper alloy having a lamellar structure and thereafter heating the conductor layer 4.

For example, the base insulating layer 3 is laminated on the metal support substrate 2, and further the conductor layer 4 is laminated on the base insulating layer 3. At this time, for example, the conductor layer 4 is formed using a copper alloy having a lamellar structure by a subtractive method. Next, the conductor layer 4 is thermally treated.

At this time, by heating the conductor layer 4 under the above-described conditions, a copper alloy having a sea-island structure is formed. That is, the conductor layer 4 containing a copper alloy having the above-described sea-island structure can be formed by heating the conductor layer 4 in the step of forming a conductor layer 4.

Further, for example, a copper alloy having the sea-island structure can be formed by heating the conductor layer 4 in the step of forming a cover insulating layer 5.

For example, the base insulating layer 3 is laminated on the metal support substrate 2, and further the conductor layer 4 is laminated on the base insulating layer 3. At this time, for example, the conductor layer 4 is formed using a copper alloy having a lamellar structure by a subtractive method. Next, a varnish as the material of the cover insulating layer 5 is applied to the base insulating layer 3 and the conductor layer 4, and thereafter the varnish is heated to form the cover insulating layer 5. At this time, the conductor layer 4 is heated together with the varnish under the above-described conditions to form a copper alloy containing a sea-island structure. That is, the conductor layer 4 containing a copper alloy having the sea-island structure can be formed by heating the conductor layer 4 in the step of forming a cover insulating layer 5.

Also in such a case, the wiring circuit board 1 suitably has excellent mechanical strength and excellent conductivity.

That is, the conductor layer 4 contains a copper alloy, and the copper alloy contains a first metal consisting of copper and a second metal that can be alloyed with copper. Therefore, the above-described wiring circuit board 1 has excellent mechanical strength.

Then, in the above-described conductor layer 4, the copper alloy has a sea-island structure, and the sea-island structure includes a sea portion having a continuous shape and an island portion having a discontinuous shape. Therefore, the above-described wiring circuit board 1 has excellent conductivity derived from the copper in the sea portion.

Furthermore, when the conductor layer 4 contains a copper alloy having the sea-island structure, the metal support substrate 2 may not contain a copper alloy having the above-described sea-island structure. Alternatively, both the metal support substrate 2 and the conductor layer 4 may contain the copper alloy having the above-described sea-island structure.

In other words, in the above-described method of producing the wiring circuit board 1, the metal support substrate 2 and/or the conductor layer 4 are/is heated to form a copper alloy having the sea-island structure. Further, the metal support substrate 2 and/or the conductor layer 4 contain(s) a copper alloy having a sea-island structure.

Preferably, in the above-described method of producing the wiring circuit board 1, the metal support substrate 2 (specifically, the original sheet 20) is heated. Further, the metal support substrate 2 contains a copper alloy having the sea-island structure.

When the metal support substrate 2 does not contain a copper alloy having the sea-island structure, the material of the metal support substrate 2 is not particularly limited. More specifically, the material of the metal support substrate 2 may be, for example, a copper alloy having no sea-island structure, or may be a metal other than a copper alloy. Examples of the metal other than a copper alloy include copper and stainless steel.

Although not detailed, in the above-described wiring circuit board 1, the cover insulating layer 5 is an arbitrary layer, and the cover insulating layer 5 may be omitted as necessary.

### EXAMPLES

With reference to Examples and Comparative Examples below, the present invention is more specifically described. The present invention is not limited to Examples and Comparative Examples in any way. The specific numeral values used in the description below, such as blending ratios (content ratios), physical property values, and parameters, can be replaced with the corresponding blending ratios (content ratios), physical property values, and parameters in the above-described “DESCRIPTION OF THE EMBODIMENT”, including the upper limit values (numeral values defined with “or less” or “less than”) or the lower limit values (numeral values defined with “or more”or “more than”).

### 1. Sample Production

### Reference Comparative Example 1

As an original sheet, a commercially available rolled copper alloy (a thickness of 30 μm) was prepared. The copper alloy was a copper-titanium alloy containing copper as the first metal and titanium as the second metal. In the copper alloy, the content ratio of copper was 96.3% by mass, and the content ratio of titanium was 3.7% by mass.

### Reference Example 1

The original sheet of Reference Comparative Example 1 was heated at 400° C. for 4 hours to obtain a heated substrate (a thickness of 30 μm). That is, the heated substrate was the above-described copper-titanium alloy that was rolled and heated.

### 2. Evaluations

### (1) SEM Photography

Using a scanning electron microscope (SEM), the cross section of the original sheet of Reference Comparative Example 1 along the rolling direction and the cross section of the heated substrate of Reference Example 1 along the rolling direction were photographed and the images thereof were observed.

The photography machine and conditions are described below.
Machine: S-4800, manufactured by Hitachi
Condition: Accelerating voltage 3 kV

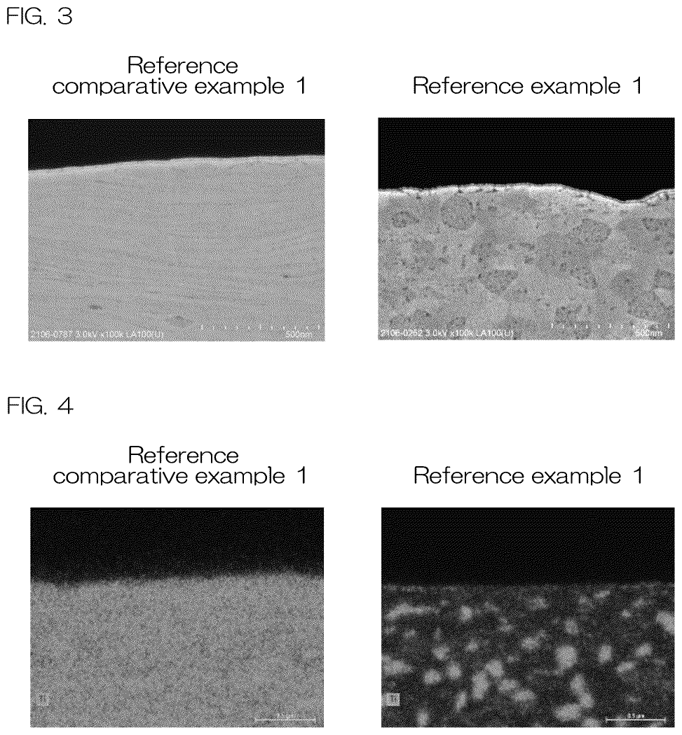

As a result of the above-described observation, it was confirmed that the original sheet of Reference Comparative Example 1 had a lamellar structure. It was also confirmed that the heated substrate of Reference Example 1 had a sea-island structure. The SEM images of Reference Comparative Example 1 and Reference Example 1 are shown in FIG. 3.

Furthermore, in the SEM image of the heated substrate of Reference Example 1, the number-average particle diameter of the island portion was determined by an SEM method. More specifically, in the image (i.e., SEM image) of the cross section of the heated substrate (copper alloy) of Reference Example 1 captured by a scanning electron microscope (SEM), the particle diameters of ten islands of the island portion were measured, and the average thereof was calculated as the number-average particle diameter.

The number-average particle diameter of the island portion was 250 nm.

### (2) EDX Analysis

Using an energy-dispersive X-ray (EDX) analyzer, the elemental mapping was carried out on the cross section of the original sheet of Reference Comparative Example 1 along the rolling direction and the cross section of the heated board of Reference Example 1 along the rolling direction. Then, the distribution of titanium atoms was observed.

The analyzer and conditions are shown below.
[Mapping]
   Analyzer: XFlash FlatQUAD, manufactured by Bruker
   Condition: Accelerating Voltage: 5 kV
[Point Analysis]
   Analyzer: X-MAX 150, manufactured by Horiba
   Condition: Accelerating Voltage: 5 kVm, 15 kV

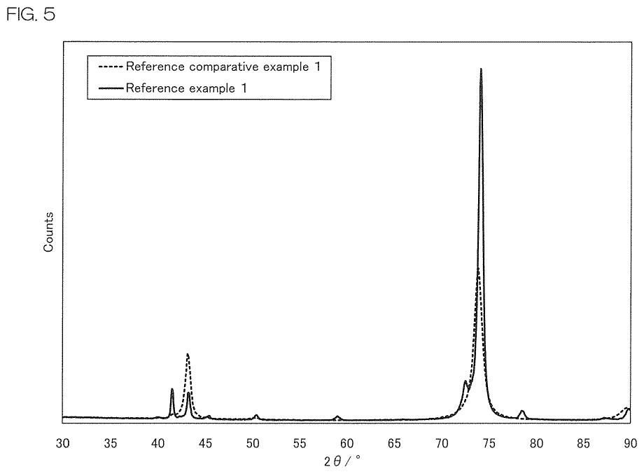

As a result of the above-described analyses, it was confirmed that the original sheet of Reference Comparative Example 1 did not have a sea-island structure. It was also confirmed that the heated substrate of Reference Example 1 had a sea-island structure. FIG. 4 shows EDX images (distribution of titanium atoms) of Reference Comparative Example 1 and Reference Example 1. FIG. 4 shows the distribution of titanium atoms in a light color.

Furthermore, from the above-described elemental mapping, the atomic distribution of the sea portion and the atomic distribution of the island portion in the sea-island structure were calculated, and the mass ratio and the atomic ratio of copper and the mass ratio and the atomic ratio of titanium were obtained.

As a result, in the sea portion, the mass ratio of copper was 100% by mass, and the atomic ratio of copper was 100 atomic %. Further, in the sea portion, the mass ratio of titanium was 0% by mass, and the atomic ratio of titanium was 0 atomic %.

On the other hand, in the island portion, the mass ratio of copper was 88.55% by mass, and the atomic ratio of copper was 85.36 atomic %. Further, in the island portion, the mass ratio of titanium was 11.45% by mass, and the atomic ratio of titanium was 14.64 atomic %.

That is, with respect to the atomic ratio (14.64 atomic %) of titanium in the island portion, the atomic ratio (0 atomic %) of titanium in the sea portion is 0 times.

### (3) XRD

Using an X-ray diffraction (XRD) analyzer, the original sheet of Reference Comparative Example 1 and the heated substrate of Reference Example 1 were each subjected to an X-ray diffraction analysis to obtain an XRD chart. The obtained XRD chart is shown in FIG. 5.

The analyzer and conditions are shown below.
Analyzer: D8 Discover with GADDS, manufactured by Bruker
Conditions: X-ray source CuKα, Voltage 50 kV, Current 100 mA, and Detector VANTEC-500

A peak having a peak top in a range of 2θ values of 41.00° or more to 42.00° or less was confirmed in the XRD chart of the heated substrate of Reference Example 1. The peak having a peak top in a range of 2θ values of 41.00° or more to less than 42.00° was a peak derived from Cu₃Ti and/or Cu₄Ti.

On the other hand, a peak having a peak top in a range of 2θ values of 41.00° or more to 42.00° or less was not confirmed in the XRD chart of the original sheet of Reference Comparative Example 1.

### (4) Conductivity

A conductivity of the original sheet of Reference Comparative Example 1 at 20° C. and a conductivity of the heated substrate of Reference Example 1 at 20° C. were measured in conformity with JIS H0505 (1975).

As the conductivity, the conductivity in the rolling direction (MD direction) (hereinafter, MD conductivity), and the conductivity in the direction perpendicular to the rolling direction (TD direction) (hereinafter, TD conductivity) were measured.

The original sheet of Reference Comparative Example 1 had an MD conductivity of 8% IACS and a TD conductivity of 8% IACS. The heated substrate of Reference Example 1 had an MD conductivity of 22% IACS and a TD conductivity of 18% IACS.

That is, it was confirmed that the conductivity of the heated substrate of Reference Example was higher than that of the original sheet of Reference Comparative Example.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### Industrial Applicability

The wiring circuit board of the present invention and the method of producing the wiring circuit board are preferably used in the fields of wiring circuit boards for electronic equipment (wiring circuit boards for electronic components) and wiring circuit boards for electrical equipment (wiring circuit boards for electrical components).

### DESCRIPTION OF REFERENCE NUMERALS

1 Wiring circuit board
2 Metal support substrate
3 Base insulating layer
4 Conductor Layer
5 Cover insulating layer
11 Divided body
20 Original sheet
21 Heated substrate

1. A wiring circuit board comprising:
a metal support substrate;
a base insulating layer disposed on a one-side surface of the metal support substrate in a thickness direction; and
a conductor layer disposed on a one-side surface of the base insulating layer in the thickness direction,
wherein the metal support substrate and/or the conductor layer contain(s) a copper alloy,
wherein the copper alloy contains:
a first metal consisting of copper; and
a second metal that can be alloyed with the copper, and
wherein in the metal support substrate and/or the conductor layer, the copper alloy has a sea-island structure including a sea portion having a continuous shape and an island portion having a discontinuous shape.

2. The wiring circuit board according to claim 1,
wherein with respect to an atomic ratio of the second metal in the island portion, an atomic ratio of the second metal in the sea portion is 0.9 times or less.

3. The wiring circuit board according to claim 1,
wherein the second metal is titanium.

4. The wiring circuit board according to claim 1,
wherein in an XRD chart obtained by measuring an X-ray diffraction (XRD) of the copper alloy, a peak having a peak top in a range of 2θ values of 41.00° or more to 42.00° or less is confirmed.

5. The wiring circuit board according to claim 1,
wherein a number-average particle diameter of the island portion is 50 nm or more, the number-average particle diameter being measured by using a scanning electron microscope (SEM).

6. A method of producing the wiring circuit board according to claim 1, the method comprising:
a step of preparing a metal support substrate;
a step of forming a base insulating layer on a one-side surface of the metal support substrate in a thickness direction;
a step of forming a conductor layer on a one-side surface of the base insulating layer in the thickness direction; and
a step of heating the metal support substrate and/or the conductor layer,
wherein the metal support substrate and/or the conductor layer contain(s) a copper alloy,
wherein the copper alloy contains:
a first metal consisting of copper; and
a second metal that can be alloyed with the copper, and
wherein a heating temperature in the heating is 350° C. or more.
